(19) United States
(12) Patent Application Publication
(10) Pub. No.: US 2005/0097414 A1
(43) Pub. Date: May 5, 2005

(54) Apparatus and method for performing poll commands using JTAG scans

(76) Inventors: Lee A. Larson, Katy, TX (US); Henry R. Hoar, Missouri City, TX (US); Huimin Xu, Missouri City, TX (US)

Correspondence Address: TEXAS INSTRUMENTS INCORPORATED, P O BOX 655474, M/S 3999, DALLAS, TX, 75265, US

(21) Appl. No.: 10/966,659

(22) Filed: Oct. 15, 2004

Related U.S. Application Data
(60) Provisional application No. 60/517,580, filed on Nov. 5, 2003.

(51) Int. Cl. G01R 31/28

(52) U.S. Cl. 714/726

(57) ABSTRACT

In a JTAG test and debug configuration for testing a target processor, the scan controller includes apparatus for performing the polling operation without the intervention of the test and debug unit. The test and debug unit transfers a command and an expected value to the scan controller. In response to the command and the expected value, the scan controller repeatedly polls the selected location to determine if the expected value is present. When the expected value is identified, the test and debug unit is notified. Provision is made for a timeout of the polling procedure to prevent the polling procedure from monopolizing the scan controller activity.

This application claims priority under 35 USC §119(e)(1) of Provisional Application No. 60/517,580 (TI-36633P) filed Nov. 05, 2003.

### FIELD OF THE INVENTION

This invention relates generally to the testing of digital signal processing units, and more particularly to techniques for performing queries between the target digital signal processor and the test and debug unit.

### BACKGROUND OF THE INVENTION

As the complexity and number of components on a processing unit chip have increased, the difficulty in testing these chips has increased. One standardized test protocol is the JTAG (Joint Test Action Group) protocol. Referring to FIG. 1, in this test environment, a test and debug unit 5, in response to user inputs applies control and data signals to scan controller 10. The scan control formats the control and data signals and transfers these signals to the target processing unit, the unit under test. The target processing unit 15 performs the activity defined by the control signals and returns the results of the test procedure to the scan control unit 10 with a serial transfer of data. The scan control unit 15 reformats the test result signals from the target processing unit 15 and transfers these signals to the test and debug unit 5 for analysis.

Referring to FIG. 2, a block diagram of the scan controller is shown. The test and debug apparatus enters control signals for the scan controller 10 into the scan controller command register 11. The command register distributes control signals throughout the scan controller 10 to implement the test activity. The test and debug unit 5 also enters test and data signals into input register 12. The test and data signals are entered into the data generator 14. The data generator 14 reformats the test and data signals and applies the reformatted signals to the target processing unit 8. Data generator 14 exchanges signals with the sequence generator 15. The sequence generator 15, in response to the signals exchanged with the data generator 14 and the control signals received from the command register 11, applies test mode signals to the target processing unit 8. The target processing unit 8, in response to the signals from the data generator 14 and the sequence generator 15, performs the test/debug procedure defined by the test and data signals. After execution of the activity defined by the test and data signals by the target processing unit 8, the results of the test procedure are transferred to the data generator 14. The test result procedure are reformatted and applied to the output register 17. The results of the test procedure are then transferred from the output register to the test and debug unit 5. The test results are then analyzed by the test and debug unit 5 to determine how to proceed with the testing of the target processor.

One common test procedure is “polling”. In polling, a value found at a selected location in the target processor is repeatedly examined until an expected value is found at that location. For each access of the selected location, the same signals much be transferred from the test and debug unit 5 to the scan controller 10 to be forwarded to the target processing unit 8. In addition, the value retrieved from the selected location must be transferred to the test and debug unit 5 to determine whether the expected value was found selected. Thus, the polling procedure requires extensive communication between the components of the testing apparatus. Each individual poll of the selected location requires multiple clock cycles before a determination is made whether the procedure must be repeated.

A need has been felt for apparatus and an associated method having the feature of improving the efficiency of the polling operation. It would be a further feature of the apparatus and associated method to provide a comparison between a selected location value and an expected value in the scan controller. It is yet another feature of the present invention, that the polling operation can be implemented in the scan controller without intervention of the test and debug unit. It is still another feature of the present invention to provide apparatus in the scan controller that permits the value retrieved from a selected location to be compared with the expected value in the scan controller. It would be still another feature of the present invention to provide for a plurality of polling operations by the scan controller in response to a command and expected value from the test and debug apparatus.

### SUMMARY OF THE INVENTION

The aforementioned features are accomplished, according to the present invention, by apparatus that permits the polling procedure, in response to a predetermined command, to be implemented without interaction with the test and debug apparatus. A scan command, a target system command, a maximum attempt count, an expected value and a data mask are transferred to and stored in the scan controller. In response to the scan command and the target system command, the value from the selected location in the target processing unit is transferred to the scan controller and compared with the expected value and don't care bits are masked off. When the value from the selected location is not the same as the expected value, a counter is incremented and the operation is repeated. The operation is repeated until the expected value is found or until the count in the counter reaches the maximum attempt count. When the value at the selected location is equal to the selected value, then the scan controller notifies the test and debug unit of the successful completion of the poll operation. When, after repeated polling operations, the count in the counter reaches the maximum attempt count, then a time-out signal is transmitted to the test and debug unit and the polling operation is terminated.

Other features and advantages of present invention will be more clearly understood upon reading of the following description and the accompanying drawings and the claims.

### BRIEF DESCRIPTION OF THE DRAWINGS

FIG. 1 is a block diagram of the configuration for testing a target processing unit using the JTAG protocol according to the prior art.

FIG. 2 is a block diagram of a scan controller according to the prior art.

FIG. 3 is a block diagram of scan controller according to the present invention.

FIG. 4 is a block diagram of a poll command unit according to the prior art.

### DESCRIPTION OF THE PREFERRED EMBODIMENT

1. Detailed Description of the Figures

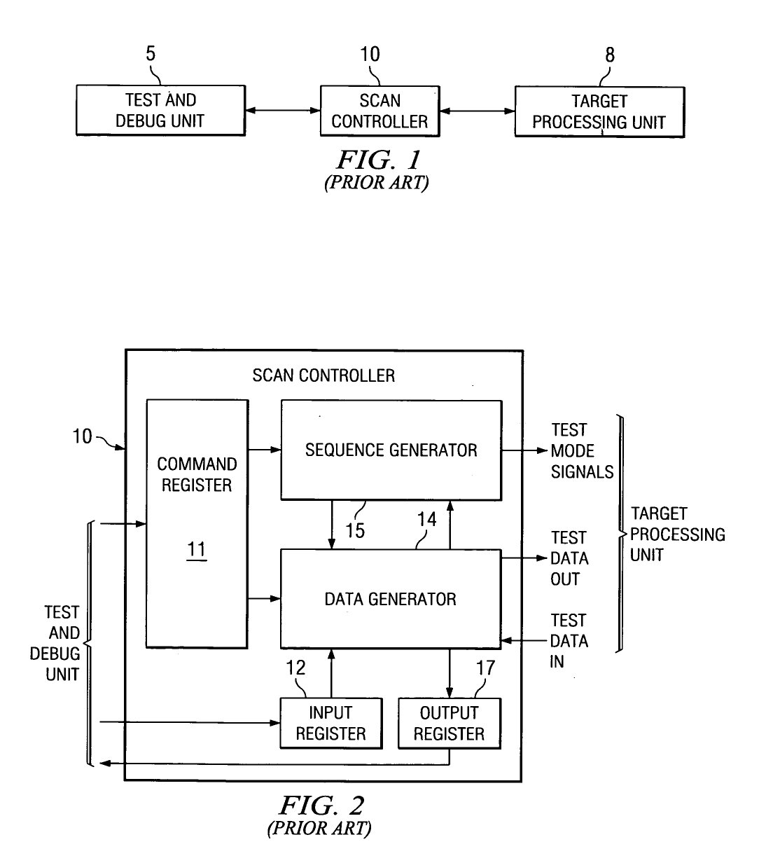

FIG. 1 and FIG. 2 have been described with respect to the prior art.

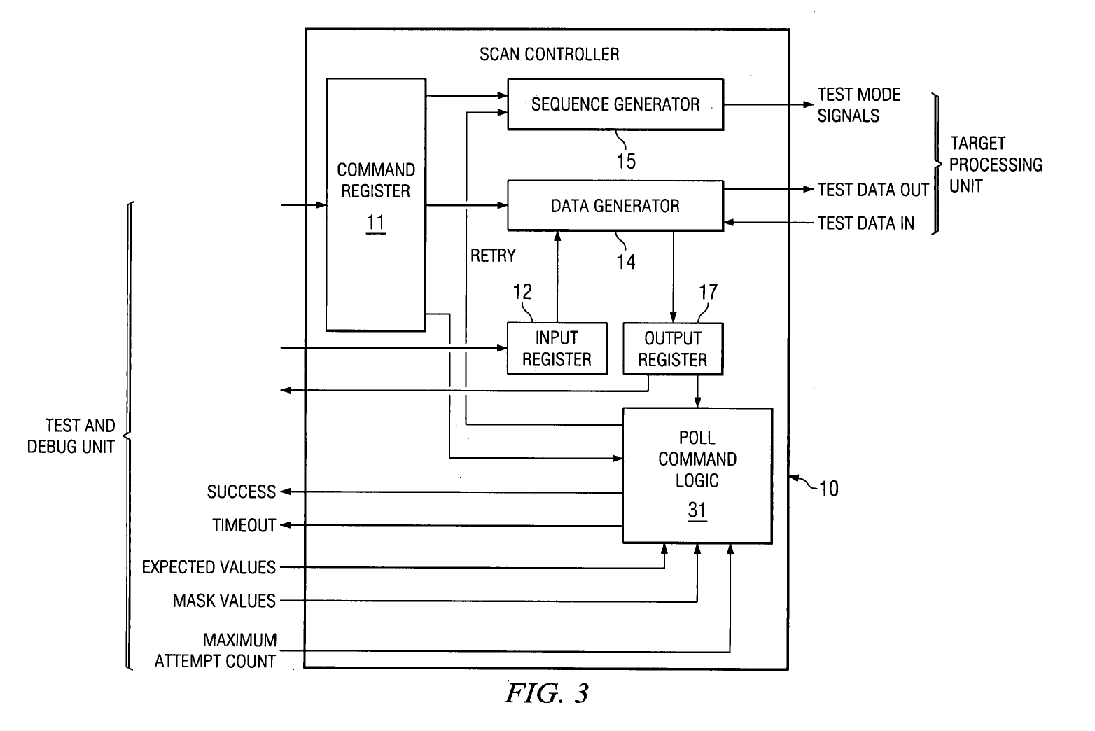

Referring to FIG. 3, a block diagram of the scan controller 30 according to the present invention is shown. The scan controller 30 includes the command register 11, the sequence generator 15, the data generator 14, the input register 12 and the output register 17 as shown in FIG. 2. In addition, the scan controller 30 includes the poll command logic 31. The poll command logic 31 receives command signals from command register 11, and signals from the output register 17. The poll command logic 31 applies a retry signal to the sequence generator 15. The poll command logic applies a success and a timeout signal to the test and debug unit, the success and timeout signals indicating to the test and debug unit whether the polling operation has been successful or not. The poll command logic unit 31 receives an expected values signal, a mask values signals, and a maximum attempt count signal from the test and debug unit.

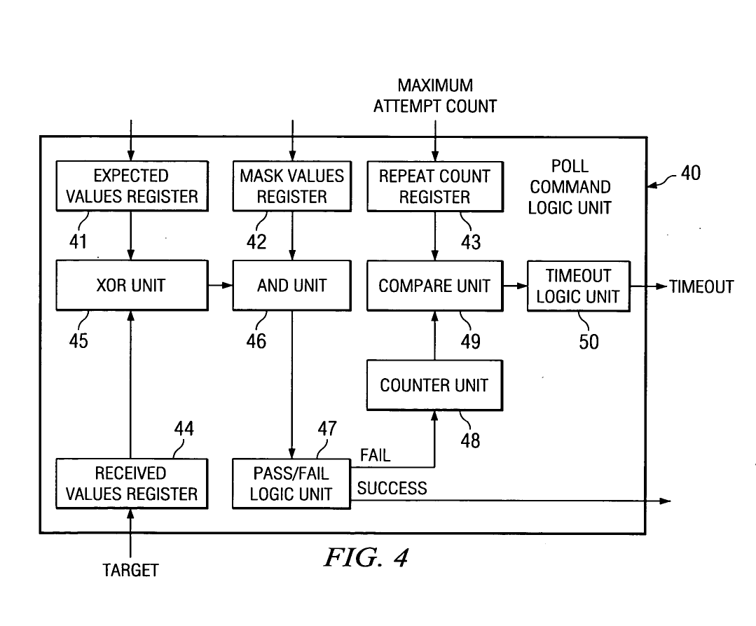

Referring to FIG. 4, a functional block diagram of the poll command logic unit 40, according to the present invention, is shown. The expected value, i.e., the value that is being sought by the polling operation, is entered in the expected values register 41 by the test and debug unit. Similarly, the test and debug program loads any mask values in the mask values register 42 and loads the maximum attempt count into the repeat count register 43. In response to the transfer of a data signal group from the scan control unit to the target processing unit, a signal group is returned from the target processing unit and entered in the received values register 44. The value in the expected values register 41 and the value in the received values register 44 are applied to logic EXCLUSIVE-OR unit 45. The output signal from logic EXCLUSIVE-OR unit 45 and the signal from the mask values unit are applied to logic AND unit 46. The output signal from the logic AND gate 46 is applied to pass/fail logic unit 47. The pass/fail logic unit 47 generates either a pass signal or a fail signal depending on the signal applied thereto. When a fail signal is generated, this signal is applied to counter unit 48. The counter unit 48 has a count value stored therein incremented by one. The count value stored in the counter unit 49 and the repeat count stored in repeat counter register 43 are applied to compare unit 49. the output signal of compare unit 49 is applied to timeout logic unit 50. When preselected conditions are met, the timeout logic unit 50 issues a time out signal.

2. Operation of the Preferred Embodiment

The operation of the scan control unit of the present invention can be understood as follows. The test and debug unit applies a poll command to the command register. The control signals provided by the command register insure that the poll operation is performed solely by the scan controller. The test and debug unit stores the expected values, the maximum attempt count values, and the mask values in registers in the poll command logic. The test and debug unit then transfers to the input register the data and the commands that will permit the scan controller to poll the target processing unit. The data and commands applied to the input register are then applied to the data generator and to the sequence generator. The data and commands are reformatted and transferred to the target processing wherein the values at the selected location are retrieved and transferred to the data generator (i.e., the test data in signals). The values retrieved from the selected location are then applied to the retrieved values register and compared with the expected values in the expected values register. The AND logic unit eliminates the values at irrelevant locations and the resulting signal group is applied to the pass/fail logic unit.

When the retrieved values are the same as the expected values, a success signal is applied to the test and debug unit indicating that the polling operation was a success. When the retrieved values and the expected values are not the same, a retry signal is applied to the sequence generator and another polling operation is performed. The application of a signal to the counter and associated signal provides a means of ending the sequence of polling operations. The test and debug unit are notified of failure to find the expected values by a timeout signal.

As will be clear, the present invention provides a more efficient technique for polling a selected location. The polling operation is performed entirely by the scan controller without further exchange of signals with the test and debug unit. The test and debug unit provides the scan controller with command and the data necessary to continuously poll a selected location and once this information is received by the scan controller, the process proceeds automatically.

While the invention has been described with respect to the embodiments set forth above, the invention is not necessarily limited to these embodiments. Accordingly, other embodiments, variations, and improvements not described herein are not necessarily excluded from the scope of the invention, the scope of the invention being defined by the following claims.

1. In test and debug system for testing a value generated by a component of a target processing unit, the system including a test and debug unit and a scan controller, the test and debug unit including a processor. the scan controller including a poll command logic unit, the poll command unit comprising:
a first storage unit responsive to signals from the processor, the first storage unit storing an expected value;
a second storage unit responsive to signals from the target processing unit, the second storage unit storing signals from a preselected component of the target processing unit; and
a first comparison unit, the comparison unit comparing signals in the first storage unit with signals in the second storage unit; when the comparison is true the comparison unit issues a first signal, when the comparison is false the comparison issues a second signal,

2. The poll command logic as recited in claim 1 wherein the first signal is a success signal and the second signal is a retry signal.

3. The poll command logic as recited in claim 1 further comprising:
a third storage unit, the third storage unit storing a repeat count;
a counter unit, the counter unit incrementing a stored value for each second signal; and
a second comparison unit, the second comparison unit comparing the counter unit stored value and the count unit, when the comparison is true the comparison unit issues a timeout signal.

4. The poll command unit as recited in claim 1 wherein the poll command logic is responsive to at least one control signal from a command register in the scan controller to generate the first and the second signals.

5. The poll command unit as recited in claim 1 wherein the test and debug system operates under the JTAG protocol.

6. In a system for testing a target processing unit; the system having a test and debug unit, a scan controller, and a target processing unit: the method of performing polling operation comprising:
providing the scan controller with first apparatus to determine when a polling operation is successful; and
when a polling operation is not successful, providing the scan controller with second apparatus to retry the polling operation without interaction with the test and debug apparatus.

7. The method as recited in claim 5 further comprising terminating the polling procedure after a predetermined number of polling operations.

8. A test and debug system for providing a JTAG polling procedure on a location in a target processing unit, the system comprising:
a test and debug unit for generating commands and data; and
a scan controller for performing the polling procedure in response to the commands and the data from the test and debug unit, the scan controller including:
a poll command logic unit, the poll command logic unit having:
first storage unit storing expected values; and
a comparison unit for comparing the expected values with values retrieved from the location, the comparison unit issuing a retry poll operation signal when the expected values and the retrieved values are not equal.

9. The system as recited in claim 8 wherein the poll command logic further has;
a second storage register storing repeat count values; and
a counter, the counter being incremented for each retry poll signal issued; and
a second comparator, the second comparator issuing a timeout signal when the count in the counter equals the repeat count values.

10. The system as recited in claim 8 wherein the scan controller includes a command register, the command register storing a first command received from the test and debug unit, the first command resulting in the polling procedure being performed by the scan controller.
